(19) United States
(12) Patent Application Publication
(10) Pub. No.: US 2026/0047262 A1
(43) Pub. Date: Feb. 12, 2026

(54) LIGHT-EMITTING ASSEMBLY AND TOUCH DISPLAY SCREEN

(71) Applicant: HKC CORPORATION LIMITED, Shenzhen (CN)

(72) Inventors: Dongmei WEI, Shenzhen (CN); Haijiang YUAN, Shenzhen (CN)

(73) Assignee: HKC CORPORATION LIMITED, Shenzhen (CN)

(21) Appl. No.: 19/293,468

(22) Filed: Aug. 7, 2025

(30) Foreign Application Priority Data
Aug. 9, 2024 (CN) 202411089091.0

(51) Int. Cl. H10H 29/85; G06F 3/041; G06F 3/042; H01L 25/16; H10H 29/14

(52) U.S. Cl. CPC H10H 29/857; G06F 3/0412; G06F 3/042; H01L 25/167; H10H 29/142

(57) ABSTRACT

A light-emitting assembly and a touch display screen are provided. The light-emitting assembly includes a first light-emitting device, a second light-emitting device, a first anode block, a second anode block, a first cathode block, and a second cathode block. Two adjacent first cathode blocks are electrically connected to each other. One first cathode block is electrically connected to one first light-emitting device. Two adjacent second cathode blocks are electrically connected to each other. One second cathode block is electrically connected to one second light-emitting device. Multiple first cathode blocks form a first touch electrode, and multiple second cathode blocks form a second touch electrode. A first electrical connection unit is electrically connected between the first touch electrode and the second touch electrode.

### CROSS-REFERENCE TO RELATED APPLICATION

This application claims priority under 35 U.S. C. § 119(a) to Chinese Patent Application No. 202411089091.0, filed Aug. 9, 2024, the entire disclosure of which is incorporated herein by reference.

### TECHNICAL FIELD

The present disclosure relates to the field of display screen technology, and in particular, to a light-emitting assembly and a touch display screen.

### BACKGROUND

With the development of internet of things (IOT) technology, human-computer interaction has become increasingly frequent, and the application of screens with touch control and display functions has become increasingly widespread. The in-cell screen technology integrating touch control into display has gained popularity in the market as it can bring advantages such as narrow bezels, lightweight and thinness, and cost reduction. However, in the related art, in-cell screens exhibit poor uniformity during display.

### SUMMARY

In an aspect, the disclosure provides a light-emitting assembly including a light-emitting module, an anode module, a cathode module, and a first electrical connection unit. The light-emitting module includes at least one first light-emitting unit and at least one second light-emitting unit. The at least one first light-emitting unit each includes multiple first light-emitting devices, and the at least one second light-emitting unit each includes multiple second light-emitting devices. The anode module includes at least one first anode unit and at least one second anode unit. The at least one first anode unit is disposed on one side of the at least one first light-emitting unit and each includes multiple first anode blocks, and one of the multiple first anode blocks is electrically connected to one of the multiple first light-emitting devices. The at least one second anode unit is disposed on one side of the at least one second light-emitting unit and each includes multiple second anode blocks, and one of the multiple second anode blocks is electrically connected to one of the multiple second light-emitting devices. The cathode module includes at least one first cathode unit and at least one second cathode unit. The at least one first cathode unit is disposed on one side of the at least one first light-emitting unit facing away from the at least one first anode unit and each includes multiple first cathode blocks, adjacent two of the multiple first cathode blocks are electrically connected to each other, and one of the multiple first cathode blocks is electrically connected to one of the multiple first light-emitting devices.

The at least one second cathode unit is disposed on one side of the at least one second light-emitting unit facing away from the at least one second anode unit and each includes multiple second cathode blocks, adjacent two of the multiple second cathode blocks are electrically connected to each other, and one of the multiple second cathode blocks is electrically connected to one of the multiple second light-emitting devices. One or more of the at least one first cathode unit form a first touch electrode, and one or more of the at least one second cathode unit form a second touch electrode. The first electrical connection unit is electrically connected between the first touch electrode and the second touch electrode. The first electrical connection unit is in a first state during a display period to make the first touch electrode electrically connected to the second touch electrode, and the first electrical connection unit is in a second state during a touch period to make the first touch electrode disconnected from the second touch electrode.

In another aspect, the disclosure further provides a touch display screen including a light-transmitting cover plate and a light-emitting assembly. The touch display screen includes multiple light-emitting assemblies disposed in a same layer, and the light-transmitting cover plate covers a light-emitting side of the multiple the light-emitting assemblies. The light-emitting assembly includes a light-emitting module, an anode module, a cathode module, and a first electrical connection unit. The light-emitting module includes at least one first light-emitting unit and at least one second light-emitting unit. The at least one first light-emitting unit each includes multiple first light-emitting devices, and the at least one second light-emitting unit each includes multiple second light-emitting devices. The anode module includes at least one first anode unit and at least one second anode unit. The at least one first anode unit is disposed on one side of the at least one first light-emitting unit and each includes multiple first anode blocks, and one of the multiple first anode blocks is electrically connected to one of the multiple first light-emitting devices. The at least one second anode unit is disposed on one side of the at least one second light-emitting unit and each includes multiple second anode blocks, and one of the multiple second anode blocks is electrically connected to one of the multiple second light-emitting devices. The cathode module includes at least one first cathode unit and at least one second cathode unit. The at least one first cathode unit is disposed on one side of the at least one first light-emitting unit facing away from the at least one first anode unit and each includes multiple first cathode blocks, adjacent two of the multiple first cathode blocks are electrically connected to each other, and one of the multiple first cathode blocks is electrically connected to one of the multiple first light-emitting devices. The at least one second cathode unit is disposed on one side of the at least one second light-emitting unit facing away from the at least one second anode unit and each includes multiple second cathode blocks, adjacent two of the multiple second cathode blocks are electrically connected to each other, and one of the multiple second cathode blocks is electrically connected to one of the multiple second light-emitting devices. One or more of the at least one first cathode unit form a first touch electrode, and one or more of the at least one second cathode unit form a second touch electrode. The first electrical connection unit is electrically connected between the first touch electrode and the second touch electrode. The first electrical connection unit is in a first state during a display period to make the first touch electrode electrically connected to the second touch electrode, and the first electrical connection unit is in a second state during a touch period to make the first touch electrode disconnected from the second touch electrode.

### BRIEF DESCRIPTION OF THE DRAWINGS

In order to describe technical solutions of embodiments of the disclosure more clearly, the following will give a brief introduction to the accompanying drawings used for describing the embodiments.

FIG. 1 is a schematic front structural view of a touch display screen provided in an embodiment of the disclosure.

FIG. 2 is a schematic side structural view of a touch display screen provided in an embodiment of the disclosure.

FIG. 3 is a schematic cross-sectional structural view of a light-emitting assembly provided in an embodiment of the disclosure.

FIG. 4 is a schematic front structural view of a light-emitting module of the light-emitting assembly illustrated in FIG. 3.

FIG. 5 is a schematic front structural view of an anode module of the light-emitting assembly illustrated in FIG. 3.

FIG. 6 is a schematic front structural view of a cathode module of the light-emitting assembly illustrated in FIG. 3.

FIG. 7 is a schematic cross-sectional view of a first electrical connection unit of the light-emitting assembly illustrated in FIG. 3.

FIG. 8 is a schematic cross-sectional view of a second electrical connection unit of the light-emitting assembly illustrated in FIG. 3.

FIG. 9 is a schematic cross-sectional view of a third electrical connection unit of the light-emitting assembly illustrated in FIG. 3.

FIG. 10 is a schematic front structural view of the light-emitting assembly illustrated in FIG. 3 including a drive chip.

FIG. 11 is a schematic cross-sectional view of a fourth electrical connection unit of the light-emitting assembly illustrated in FIG. 3.

FIG. 12 is a schematic cross-sectional view of a fifth electrical connection unit of the light-emitting assembly illustrated in FIG. 3.

### DETAILED DESCRIPTION

The following will illustrate technical solutions of embodiments of the disclosure clearly and comprehensively, with reference to the accompanying drawings of embodiments of the disclosure. Apparently, embodiments described herein are merely some embodiments, rather than all embodiments, of the disclosure. Based on the embodiments of the disclosure, all other embodiments obtained by those of ordinary skill in the art without creative effort shall fall within the protection scope of the disclosure.

Reference to “embodiment” herein means that a particular feature, structure, or characteristic described in conjunction with the embodiment may be included in at least one embodiment of the present disclosure. The presence of the term at each place in the specification does not necessarily refer to the same embodiment, nor does it refer to a separate or alternative embodiment that is mutually exclusive of other embodiments. It may be understood by those skilled in the art, both explicitly and implicitly, that the embodiments described herein may be combined with other embodiments.

The terms such as “first” and “second” and the like in the specification and claims of the disclosure are used for distinguishing between different objects rather than describing a particular order. In addition, the terms “include”, “comprise”, or any other variant thereof, are intended to cover a non-exclusive inclusion. For example, assemblies or equipment that contain one or more components are not limited to the listed one or more components, but may optionally include one or more components that are not listed but are inherent to the illustrated product, or one or more components that should be included based on the described functionality.

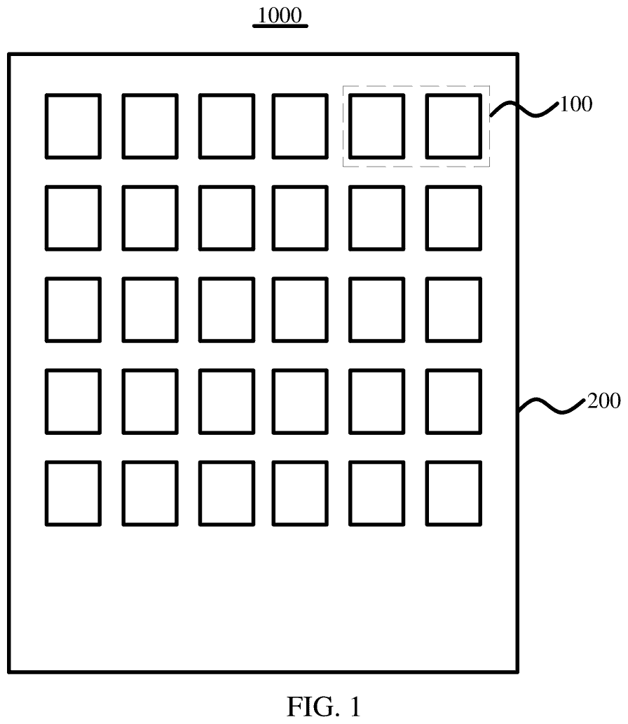

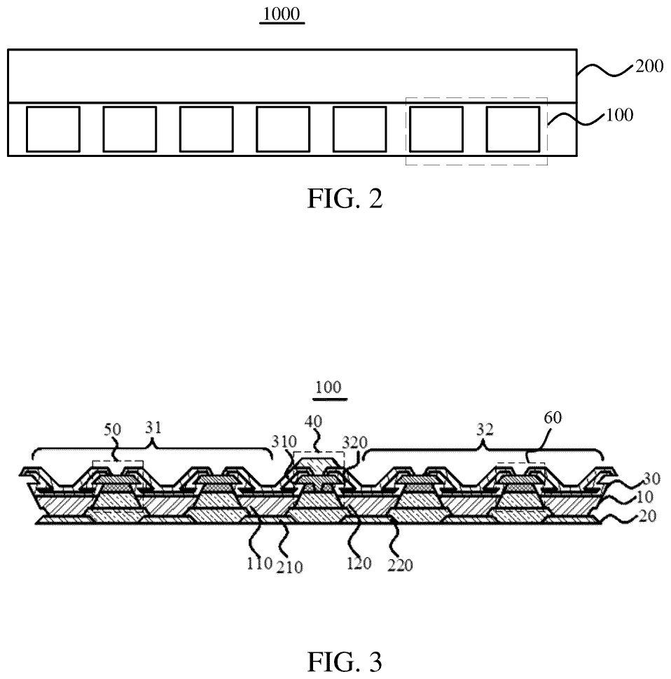

Reference is made to FIG. 1 to FIG. 3. FIG. 1 is a schematic front structural view of a touch display screen 1000 provided in an embodiment of the disclosure. FIG. 2 is a schematic side structural view of a touch display screen 1000 provided in an embodiment of the disclosure. FIG. 3 is a schematic cross-sectional structural view of a light-emitting assembly 100 provided in an embodiment of the disclosure. The touch display screen 1000 includes a light-transmitting cover plate 200 and a light-emitting assembly 100. The light-emitting assembly 100 is implemented as multiple light-emitting assemblies 100 disposed in the same layer. The light-transmitting cover plate 200 covers the light-emitting side of the light-emitting assembly 100. The light-emitting assembly 100 includes a light-emitting module 10, an anode module 20, and a cathode module 30. The anode module 20, the light-emitting module 10, and the cathode module 30 may be sequentially stacked. In the touch display screen 1000, multiple light-emitting modules 10 form a light-emitting layer, multiple anode modules 20 form an anode layer, and multiple cathode modules 30 form a cathode layer. In a possible embodiment, the anode layer may be disposed on one side of the light-emitting layer facing away from the light-transmitting cover plate 200, and the cathode layer may be disposed between the light-emitting module 10 and the light-transmitting cover plate 200. That is, the light-transmitting cover plate 200, the cathode layer, the light-emitting layer, and the anode layer are sequentially stacked. In this embodiment, the cathode module 30 of the cathode layer may be made from a transparent conductive material, for example, indium tin oxide (ITO). However, in other possible embodiments, the light-transmitting cover plate 200, the anode layer, the light-emitting layer, and the cathode layer may be sequentially stacked.

The light-transmitting cover plate 200 may be a glass cover plate. The light-transmitting cover plate 200 is configured to protect the light-emitting assembly 100. The light-transmitting cover plate 200 may be integrated with functional layers such as an oil resistance film, a fingerprint resistance film, an anti-reflection film, and a reflection reduction film.

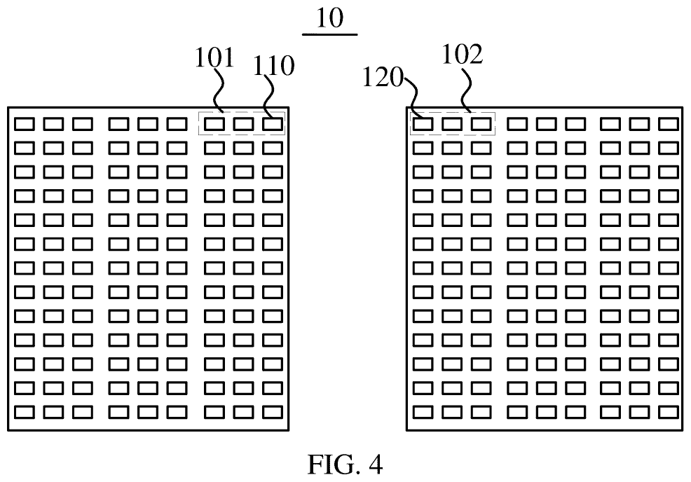

Reference is made to FIG. 3 and FIG. 4. FIG. 4 is a schematic front structural view of the light-emitting module 10 of the light-emitting assembly 100 illustrated in FIG. 3. The light-emitting module 10 is configured to emit light to achieve light-emitting display. The light-emitting module 10 includes at least one first light-emitting unit 101 and at least one second light-emitting unit 102. The first light-emitting unit 101 includes multiple first light-emitting devices 110. The second light-emitting unit 102 includes multiple second light-emitting devices 120.

The disclosure does not specifically limit the quantity of the first light-emitting units 101 included in the light-emitting module 10, the quantity of the first light-emitting devices 110 included in the first light-emitting unit 101, the quantity of the second light-emitting units 102 included in the light-emitting module 10, and the quantity of the second light-emitting devices 120 included in the second light-emitting unit 102. The quantity of the first light-emitting units 101 may be greater than or equal to one. The quantity of the first light-emitting devices 110 may be greater than or equal to two. The quantity of the second light-emitting units 102 may be greater than or equal to one. The quantity of the second light-emitting devices 120 may be greater than or equal to two. The quantity of the first light-emitting units 101 may be equal to the quantity of second light-emitting units 102. The quantity of the first light-emitting devices 110 may be equal to the quantity of second light-emitting devices 120. One first light-emitting unit 101 forms one pixel unit. One second light-emitting unit 102 forms one pixel unit. One first light-emitting device 110 forms one pixel. One second light-emitting device 120 forms one pixel. In a possible embodiment, the first light-emitting device 110 may be a semiconductor light-emitting device, for example, an organic light emitting diode (OLED), and the second light-emitting device 120 may be a semiconductor light-emitting device, for example, an OLED. It may be understood that, the light-emitting assembly 100 provided in the disclosure may be an OLED light-emitting assembly. The multiple first light-emitting devices 110 included in the first light-emitting unit 101 may include at least one red light-emitting device, at least one green light-emitting device, and at least one blue light-emitting device. The multiple second light-emitting devices 120 included in the second light-emitting unit 102 may include at least one red light-emitting device, at least one green light-emitting device, and at least one blue light-emitting device. The red light-emitting device, the green light-emitting device, and the blue light-emitting device enable full-color light-emitting display. The disclosure does not specifically limit the quantity of the red light-emitting devices, the quantity of the green light-emitting devices, and the quantity of the blue light-emitting devices in the first light-emitting unit 101. In the following embodiments, unless otherwise specified, it is assumed that the first light-emitting unit 101 includes one red light-emitting device, one green light-emitting device, and one blue light-emitting device, and the second light-emitting unit 102 includes one red light-emitting device, one green light-emitting device, and one blue light-emitting device. To reduce color interference, the first light-emitting unit 101 and the second light-emitting unit 102 may be arranged spaced apart from each other, two adjacent first light-emitting devices 110 in the first light-emitting unit 101 may be arranged spaced apart from each other, and two adjacent second light-emitting devices 120 in the second light-emitting unit 102 may be arranged spaced apart from each other.

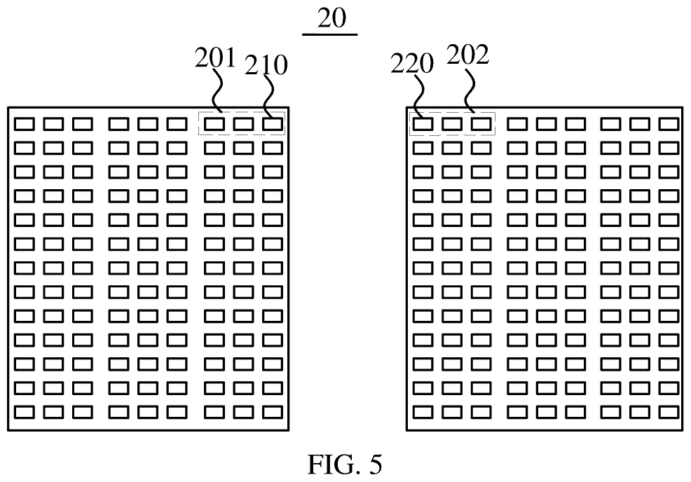

Reference is made to FIG. 3 to FIG. 5. The anode module 20 is configured to electrically connect to the positive electrode of a driving chip 70 to provide electron holes to the light-emitting module 10 under the driving of the driving chip 70. The anode module 20 includes at least one first anode unit 201 and at least one second anode unit 202. The first anode unit 201 is disposed on one side of the first light-emitting unit 101 and includes multiple first anode blocks 210. One first anode block 210 is electrically connected to one first light-emitting device 110. The second anode unit 202 is disposed on one side of the second light-emitting unit 102 and includes multiple second anode blocks 220. One second anode block 220 is electrically connected to one second light-emitting device 120.

The disclosure does not specifically limit the quantity of the first anode units 201 included in the anode module 20, the quantity of the first anode blocks 210 included in the first anode unit 201, the quantity of the second anode units 202 included in the anode module 20, and the quantity of the second anode blocks 220 included in the second anode unit 202. The quantity of the first anode units 201 may be equal to the quantity of the first light-emitting units 101. The quantity of the first anode blocks 210 may be equal to the quantity of the first light-emitting devices 110. The quantity of the second anode units 202 may be equal to the quantity of the second light-emitting units 102. The quantity of the second anode blocks 220 may be equal to the quantity of the second light-emitting devices 120. The material of the first anode block 210 and the second anode block 220 may be a transparent conductive material, for example, ITO, or may be a non-transparent conductive material, for example, a metal, an alloy, etc. The size and shape of the multiple first anode blocks 210 may be the same or different. The size and shape of the multiple second anode blocks 220 may be the same or different. In the embodiments of the disclosure, multiple first anode blocks 210 with the same size and shape, and multiple second anode blocks 220 with the same size and shape are taken as an example. The first anode block 210 and the first light-emitting device 110 may directly contact each other for electrical connection. The second anode block 220 and the second light-emitting device 120 may directly contact each other for electrical connection. In a possible embodiment, the first anode block 210 may cover one side of the first light-emitting device 110. The second anode block 220 may cover one side of the second light-emitting device 120.

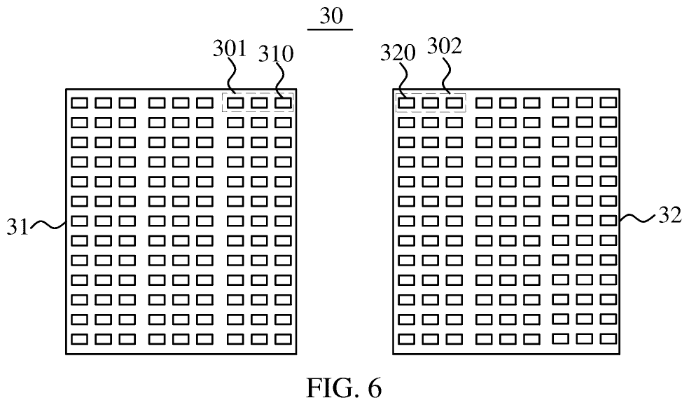

Reference is made to FIG. 3 to FIG. 6. The cathode module 30 is configured to electrically connect to the negative electrode of the driving chip 70 to provide electrons to the light-emitting module 10 under the driving of the driving chip 70. The cathode module 30 includes at least one first cathode unit 301 and at least one second cathode unit 302. The first cathode unit 301 is disposed on one side of the first light-emitting unit 101 facing away from the first anode unit 201 and includes multiple first cathode blocks 310. Two adjacent first cathode blocks 310 are electrically connected to each other. One first cathode block 310 is electrically connected to one first light-emitting device 110. The second cathode unit 302 is disposed on one side of the second light-emitting unit 102 facing away from the second anode unit 202 and includes multiple second cathode blocks 320. Two adjacent second cathode blocks 320 are electrically connected to each other. One second cathode block 320 is electrically connected to one second light-emitting device 120.

The disclosure does not specifically limit the quantity of the first cathode units 301 included in the cathode module 30, the quantity of the first cathode blocks 310 included in the first cathode unit 301, the quantity of the second cathode units 302 included in the cathode module 30, and the quantity of the second cathode blocks 320 included in the second cathode unit 302. The quantity of the first cathode units 301 may be equal to the quantity of the first light-emitting units 101. The quantity of the first cathode blocks 310 may be equal to the quantity of the first light-emitting devices 110. The quantity of the second cathode units 302 may be equal to the quantity of the second light-emitting units 102. The quantity of the second cathode blocks 320 may be equal to the quantity of the second light-emitting devices 120. The material of the first cathode block 310 and the second cathode block 320 may be a transparent conductive material, for example, ITO, or may be a non-transparent conductive material, for example, a metal, an alloy, etc. The size and shape of the multiple first cathode blocks 310 may be the same or different. The size and shape of the multiple second cathode blocks 320 may be the same or different. In the embodiments of the disclosure, multiple first cathode blocks 310 with the same size and shape, and multiple second cathode blocks 320 with the same size and shape are taken as an example. The first cathode block 310 and the first light-emitting device 110 may directly contact each other for electrical connection. The second cathode block 320 and the second light-emitting device 120 may directly contact each other for electrical connection. In a possible embodiment, the first cathode block 310 may cover one side of the first light-emitting device 110 facing away from the first anode block 210. The second cathode block 320 may cover one side of the second light-emitting device 120 facing away from the second anode block 220. Two adjacent first cathode blocks 310 in the first cathode unit 301 may be directly or indirectly electrically connected with each other. Two adjacent second cathode blocks 320 in the second cathode unit 302 may be directly or indirectly electrically connected with each other.

One or more first cathode units 301 form a first touch electrode 31, and one or more second cathode units 302 form a second touch electrode 32. In an embodiment where multiple first cathode units 301 form the first touch electrode 31, it may be two or more than two first cathode units 301 forming the first touch electrode 31. In an embodiment where multiple second cathode units 302 form the second touch electrode 32, it may be two or more than two second cathode units 302 forming the second touch electrode 32. In a possible embodiment, the quantity of the first cathode units 301 in the first touch electrode 31 may be equal to the quantity of the second cathode units 302 in the second touch electrode 32. Since the area of a finger performing touch operations in human-machine interaction is generally much larger than the area of a single pixel unit, multiple first cathode units 301 forming one first touch electrode 31 and multiple second cathode units 302 forming one second touch electrode 32 are taken as an example in the following embodiments unless otherwise specified. The first touch electrode 31 and the second touch electrode 32 are disposed adjacent to each other. Two adjacent first cathode units 301 in the first touch electrode 31 are electrically connected, and it may be directly or indirectly electrically connected. Two adjacent second cathode units 302 in the second touch electrode 32 are electrically connected, and it may be directly or indirectly electrically connected. The cathode layer may be divided into multiple first touch electrodes 31 and multiple second touch electrodes 32. Each first touch electrode 31 includes multiple first cathode blocks 310, and each second touch electrode 32 includes multiple second cathode blocks 320. The multiple first cathode blocks 310 in the first touch electrode 31 may be arranged in an array. The multiple second cathode blocks 320 in the second touch electrode 32 may be arranged in an array.

The first electrical connection unit 40 is configured to enable electrical connection or disconnection between the first touch electrode 31 and the second touch electrode 32.

Specifically, the first electrical connection unit 40 is electrically connected between the first touch electrode 31 and the second touch electrode 32. The first electrical connection unit 40 is in a first state during a display period to make the first touch electrode 31 electrically connected to the second touch electrode 32, and the first electrical connection unit 40 is in a second state during a touch period to make the first touch electrode 31 disconnected from the second touch electrode 32.

The first electrical connection unit 40 and the first cathode block 310 in the first touch electrode 31 may directly contact each other for electrical connection, and the first electrical connection unit 40 and the second cathode block 320 in the second touch electrode 32 may directly contact each other for electrical connection. In a possible embodiment, the first electrical connection unit 40 may be electrically connected between one first cathode block 310 in the first touch electrode 31 and one second cathode block 320 in the second touch electrode 32. In another possible embodiment, the first electrical connection unit 40 may be electrically connected between multiple first cathode blocks 310 in the first touch electrode 31 and multiple second cathode blocks 320 in the second touch electrode 32. For example, when the first touch electrode 31 and the second touch electrode 32 are horizontally arranged, the first electrical connection unit 40 may be electrically connected between one first cathode block 310 at the edge of each row in the first touch electrode 31 and one second cathode block 320 at the edge of each row in the second touch electrode 32. When the first touch electrode 31 and the second touch electrode 32 are vertically arranged, the first electrical connection unit 40 may be electrically connected between the first cathode blocks 310 at the edge of each column in the first touch electrode 31 and the second cathode blocks 320 at the edge of each column in the second touch electrode 32.

The cathode module 30 of the light-emitting assembly 100 provided in the disclosure includes at least one first cathode unit 301 and at least one second cathode unit 302. The first cathode unit 301 is disposed on one side of the first light-emitting unit 101 of the light-emitting module 10 facing away from the first anode unit 201, and the first cathode block 310 of the first cathode unit 301 is electrically connected to the first light-emitting device 110 of the first light-emitting unit 101. The second cathode unit 302 is disposed on one side of the second light-emitting unit 102 of the light-emitting module 10 facing away from the second anode unit 202, and the second cathode block 320 of the second cathode unit 302 is electrically connected to the second light-emitting device 120 of the second light-emitting unit 102. Therefore, the cathode module 30 can serve as an electrode for implementing display functions, while one or more first cathode units 301 form a first touch electrode 31 and one or more second cathode units 302 form a second touch electrode 32, thus enabling the cathode module 30 to also serve as an electrode for implementing touch control functions, thereby realizing the application of the in-cell technology. Additionally, since two adjacent first cathode blocks 310 are electrically connected to each other and two adjacent second cathode blocks 320 are electrically connected to each other, the light-emitting assembly 100 further includes the first electrical connection unit 40 electrically connected between the first touch electrode 31 and the second touch electrode 32. The first electrical connection unit 40 is in the first state during the display period to make the first touch electrode 31 electrically connected to the second touch electrode 32, and the first electrical connection unit 40 is in the second state during the touch period to make the first touch electrode 31 disconnected from the second touch electrode 32. In this way, during the display period, the first touch electrode 31 is electrically connected to the second touch electrode 32, such that the electrical connection in the entire cathode module 30 is achieved, voltage uniformity is achieved, and the display uniformity is improved. During the touch control period, the first touch electrode 31 is disconnected from the second touch electrode 32, and the cathode module 30 is divided into mutually independent first touch electrode 31 and second touch electrode 32, thereby enabling touch detection.

The light-emitting assembly 100 further includes a regulating circuit electrically connected to the first electrical connection unit 40. The regulating circuit is configured to provide a first driving voltage to the first electrical connection unit 40 during the display period and provide a second driving voltage to the first electrical connection unit 40 during the touch period, and the first driving voltage is higher than the second driving voltage.

The first electrical connection unit 40 and the regulating circuit may be electrically connected via a conductive lead wire. The second driving voltage may be zero. It may be understood that, the first electrical connection unit 40 is in the first state when receiving a driving voltage, such that the first touch electrode 31 is electrically connected to the second touch electrode 32. The first electrical connection unit 40 is in the second state when not receiving a driving voltage, such that the first touch electrode 31 is disconnected from the second touch electrode 32. Alternatively, the first electrical connection unit 40 is in the first state when receiving a higher driving voltage, such that the first touch electrode 31 is electrically connected to the second touch electrode 32. The first electrical connection unit 40 is in the second state when receiving a lower driving voltage, such that the first touch electrode 31 is disconnected from the second touch electrode 32.

When the first touch electrode 31 and the second touch electrode 32 are electrically connected, the cathode module 30 is in electrical connection as a whole to form a display electrode, thereby improving the display uniformity of the light-emitting assembly 100. When the first touch electrode 31 and the second touch electrode 32 are disconnected, the cathode module 30 is divided into mutually independent first touch electrode 31 and second touch electrode 32, enabling the in-cell technology and facilitating the integration of touch detection functions into the light-emitting assembly 100. In the touch display screen 1000, when all the first touch electrodes 31 and the second touch electrodes 32 in the cathode layer are electrically connected, the cathode layer as a whole is in electrical connection to form a display electrode. When all the first touch electrodes 31 and the second touch electrodes 32 in the cathode layer are disconnected, the cathode layer is divided into multiple independent touch electrodes.

By providing the regulating circuit, the first electrical connection unit 40 is switched between the first state and the second state under the regulation of the regulating circuit, and the state regulation of the first electrical connection unit 40 may be algorithm-based. Implementing state regulation of the first electrical connection unit 40 through changing the driving voltage may ensure high precision, high speed, and high reliability in the state regulation of the first electrical connection unit 40.

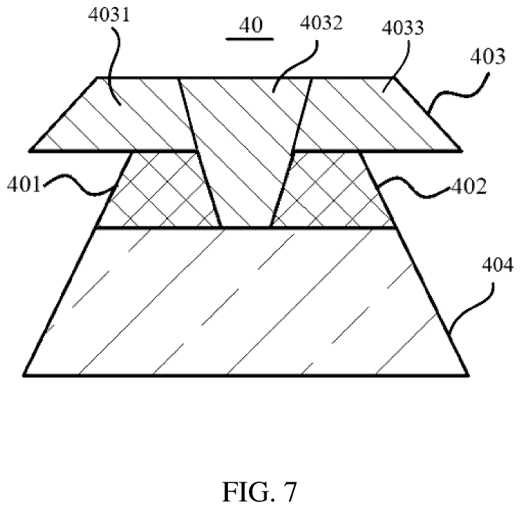

Optionally, as illustrated in FIG. 7, the first electrical connection circuit 40 includes a first conductive block 401, a second conductive block 402, and a resistance-adjustable block 403. The first conductive block 401 is electrically connected to the first cathode block 310 in the first touch electrode 31, and the second conductive block 402 is electrically connected to the second cathode block 320 in the second touch electrode 32. The resistance-adjustable block 403 is electrically connected to the regulating circuit. At least a portion of the resistance-adjustable block 403 is connected between the first conductive block 401 and the second conductive block 402, and the resistance-adjustable block 403 exhibits a low-resistance state under the first driving voltage and exhibits a high-resistance state under the second driving voltage.

The first conductive block 401 and the first cathode block 310 in the first touch electrode 31 may directly contact each other for electrical connection. The second conductive block 402 and the second cathode block 320 in the second touch electrode 32 may directly contact each other for electrical connection. The resistance-adjustable block 403 and the regulating circuit may be electrically connected via a conductive lead wire. In a possible embodiment, a regulating electrode may be disposed on one side of the resistance-adjustable block 403 facing away from the light-emitting module 10. The resistance-adjustable block 403 and the regulating electrode directly contact each other for electrical connection, and the regulating electrode is electrically connected to the regulating circuit via a conductive lead wire. One side of the resistance-adjustable block 403 may directly contact the first conductive block 401 to achieve electrical connection with the first conductive block 401, and the other side of the resistance-adjustable block 403 may directly contact the second conductive block 402 to achieve electrical connection with the second conductive block 402. Under a first driving voltage, the resistance-adjustable block 403 exhibits a low-resistance state, and the first conductive block 401 is electrically connected to the second conductive block 402. Consequently, the first cathode block 310 in the first touch electrode 31 is electrically connected to the second cathode block 320 in the second touch electrode 32, and the first touch electrode 31 and the second touch electrode 32 are electrically connected. Under a second driving voltage, the resistance-adjustable block 403 exhibits a high-resistance state, and the first conductive block 401 is disconnected from the second conductive block 402. Consequently, the first cathode block 310 in the first touch electrode 31 is disconnected from the second cathode block 320 in the second touch electrode 32, and the first touch electrode 31 and the second touch electrode 32 are mutually independent.

Since the first light-emitting unit 101 and the second light-emitting unit 102 being arranged spaced apart from each other can reduces color interference, the first cathode unit 301 and the second cathode unit 302 are typically spaced apart from each other by a certain interval. Therefore, by configuring the first electrical connection unit 40 to include the first conductive block 401 and the second conductive block 402, where the first conductive block 401 is electrically connected to the first cathode block 310 in the first touch electrode 31 and the second conductive block 402 is electrically connected to the second cathode block 320 in the second touch electrode 32, the formation of the first electrical connection unit 40 in the interval region between the first cathode unit 301 and the second cathode unit 302 may be facilitated, thereby facilitating the light and thin design of the light-emitting assembly 100. Additionally, the resistance-adjustable block 403 exhibits different resistance under different driving voltages, enabling the state regulation of the first electrical connection unit 40 under different driving voltages.

In a possible embodiment, a dielectric constant of the resistance-adjustable block 403 is greater than or equal to 15, and a band gap width of the resistance-adjustable block 403 is greater than or equal to 3 electron volt (eV).

Optionally, the material of the resistance-adjustable block 403 may include zirconium oxide (ZrO₂) and tantalum oxide (Ta₂O₅). Zirconium oxide and tantalum oxide exhibit high dielectric constants and wide band gaps. The dielectric constant of zirconium oxide is generally greater than or equal to 20, and the dielectric constant of tantalum oxide is generally greater than or equal to 26. The band gap width of zirconium oxide is generally greater than or equal to 5.8 eV, and the band gap width of tantalum oxide is generally greater than or equal to 3.7 eV.

By ensuring that the dielectric constant of the resistance-adjustable block 403 is greater than or equal to 15 and the band gap width of the resistance-adjustable block 403 is greater than or equal to 3 eV, the resistance-change characteristic of the resistance-adjustable block 403 can be ensured. This enhances the reliability of the first electrical connection unit 40 in electrically connecting or disconnecting the first touch electrode 31 and the second touch electrode 32.

In a possible embodiment, as illustrated in FIG. 7, the first conductive block 401 and the second conductive block 402 are disposed in the same layer and spaced apart from each other. The resistance-adjustable block 403 includes a first sub-resistance-adjustable block 4031, a second sub-resistance-adjustable block 4032, and a third sub-resistance-adjustable block 4033 sequentially connected. At least a portion of the first sub-resistance-adjustable block 4031 covers one side of the first conductive block 401 facing away from the light-emitting module 10, at least a portion of the second sub-resistance-adjustable block 4032 is connected between the first conductive block 401 and the second conductive block 402, and at least a portion of the third sub-resistance-adjustable block 4033 covers one side of the second conductive block 402 facing away from the light-emitting module 10. The first electrical connection unit 40 further includes a first insulating block 404 connected between the first light-emitting device 110 and the second light-emitting device 120.

At least a portion of the first cathode block 310, the first conductive block 401, the second conductive block 402, and at least a portion of the second cathode block 320 may be disposed in the same layer. The first sub-resistance-adjustable block may directly contact the first cathode block 310 in the first touch electrode 31 for electrical connection. The third sub-resistance-adjustable block may directly contact the second cathode block 320 in the second touch electrode 32 for electrical connection.

The first electrical connection unit 40 includes the first conductive block 401 and the second conductive block 402 disposed in the same layer and spaced apart from each other, a portion of the resistance-adjustable block 403 is connected between the first conductive block 401 and the second conductive block 402, and another portion of the resistance-adjustable block 403 is disposed on the sides of the first conductive block 401 and the second conductive block 402 facing away from the light-emitting module 10, so that the formation of an “overhead (OH)” structure of the first electrical connection unit 40 is facilitated, thereby facilitating the improvement of the light-emitting effect of the light-emitting assembly 100 and optimizing display performance. The arrangement of the first insulating block 404 can isolate the first light-emitting unit 101 and the second light-emitting unit 102, preventing contact between the first light-emitting device 110 and the second light-emitting device 120.

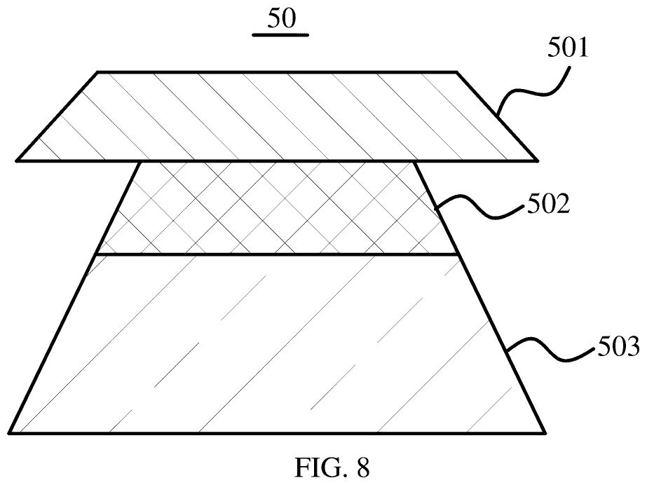

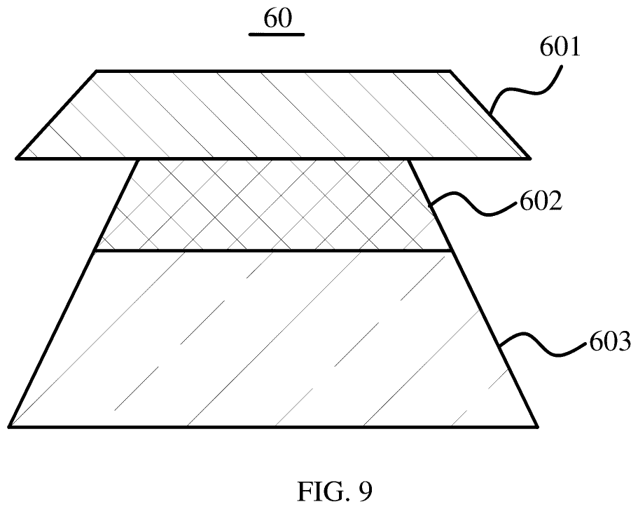

Reference is made to FIG. 3, FIG. 8, and FIG. 9. The light-emitting assembly 100 further includes at least one second electrical connection unit 50 and at least one third electrical connection unit 60. The second electrical connection unit 50 is electrically connected between two adjacent first cathode blocks 310, and the third electrical connection unit 60 is electrically connected between two adjacent second cathode blocks 320.

The embodiments of the disclosure do not specifically limit the quantity of the second electrical connection units 50 and the quantity of the third electrical connection units 60. In an embodiment where the first light-emitting unit 101 includes three light-emitting devices, i.e., a red light-emitting device, a green light-emitting device, and a blue light-emitting device, if the red light-emitting device, the green light-emitting device, and the blue light-emitting device are sequentially arranged, two second electrical connection units 50 may be provided in each first cathode unit 301. One second electrical connection unit 50 is electrically connected between a first cathode block 310 configured to electrically connect to the red light-emitting device and a first cathode block 310 configured to electrically connect to the green light-emitting device. The other second electrical connection unit 50 is electrically connected between the first cathode block 310 configured to electrically connect to the green light-emitting device and a first cathode block 310 configured to electrically connect to the blue light-emitting device. In an embodiment where the second light-emitting unit 102 includes three light-emitting devices, i.e., a red light-emitting device, a green light-emitting device, and a blue light-emitting device, if the red light-emitting device, the green light-emitting device, and the blue light-emitting device are sequentially arranged, two third electrical connection units 60 may be provided in each second cathode unit 302. One third electrical connection unit 60 is electrically connected between a second cathode block 320 configured to electrically connect to the red light-emitting device and a second cathode block 320 configured to electrically connect to the green light-emitting device. The other third electrical connection unit 60 is electrically connected between the second cathode block 320 configured to electrically connect to the green light-emitting device and a second cathode block 320 configured to electrically connect to the blue light-emitting device.

By configuring the light-emitting module group 100 to further include at least one second electrical connection unit 50 and at least one third electrical connection unit 60, where the second electrical connection unit 50 is electrically connected between two adjacent first cathode blocks 310 and the third electrical connection unit 60 is electrically connected between two adjacent second cathode blocks 320, the formation of the first touch electrode 31 from one or more first cathode units 301 and the formation of the second touch electrode 32 from one or more second cathode units 302 are facilitated, thereby realizing the application of the in-cell technology.

In a possible embodiment, the first cathode unit 301 is implemented as multiple first cathode units 301, the second cathode unit 302 is implemented as multiple second cathode units 302, and the light-emitting assembly 100 further includes at least one fourth electrical connection unit 80 and at least one fifth electrical connection unit 90. The fourth electrical connection unit 80 is electrically connected between two adjacent first cathode units 301, and the fifth electrical connection unit 90 is electrically connected between two adjacent second cathode units 302.

The embodiments of the disclosure do not specifically limit the quantity of the fourth electrical connection units 80 and the quantity of the fifth electrical connection units 90. For example, in an embodiment where N first cathode units 301 form one first touch electrode 31, the quantity of the fourth electrical connection units 80 may be N-1. In an embodiment where N second cathode units 302 form one second touch electrode 32, the quantity of the fifth electrical connection units 90 may be N-1. In this case, two adjacent first cathode units 301 are electrically connected via one fourth electrical connection unit 80, and two adjacent second cathode units 302 are electrically connected via one fifth electrical connection unit 90. Alternatively, in an embodiment where N first cathode units 301 form one first touch electrode 31 and each first cathode unit 301 includes three first cathode blocks 310, the quantity of the fourth electrical connection units 80 may be 3(N-1). In an embodiment where N second cathode units 302 form one second touch electrode 32 and each second cathode unit 302 includes three second cathode blocks 320, the quantity of the fifth electrical connection units 90 may be 3(N-1). In this case, two adjacent first cathode units 301 are electrically connected via three fourth electrical connection units 80, and two adjacent second cathode units 302 are electrically connected via three fifth electrical connection units 90. That is, the first cathode blocks 310 in one first cathode unit 301 are connected to the first cathode blocks 310 in an adjacent first cathode unit 301 in a one-to-one correspondence through the fourth electrical connection units 80. The second cathode blocks 320 in one second cathode unit 302 are connected to the second cathode blocks 320 in an adjacent second cathode unit 302 in a one-to-one correspondence through the fifth electrical connection units 90.

By configuring the light-emitting assembly 100 to further include at least one fourth electrical connection unit 80 and at least one fifth electrical connection unit 90, where the fourth electrical connection unit 80 is electrically connected between two adjacent first cathode units 301 and the fifth electrical connection unit is electrically connected between two adjacent second cathode units 302, the formation of one first touch electrode 31 from multiple first cathode units 301 and the formation of one second touch electrode 32 from multiple second cathode units 302 are facilitated in an embodiment where the cathode module 30 includes multiple first cathode units 301 and multiple second cathode units 302. This ensures that the area of each touch electrode exceeds the area of the pixel unit, making it more suitable for human-machine interaction scenarios.

The second electrical connection unit 50 includes a second insulating block 501, a third conductive block 502, and a third insulating block 503 which are stacked. The third conductive block 502 is electrically connected between two adjacent first cathode blocks 310, and the third insulating block 503 is connected between two adjacent first light-emitting devices 110. The third electrical connection unit 60 includes a fourth insulating block 601, a fourth conductive block 602, and a fifth insulating block 603 which are stacked. The fourth conductive block 602 is electrically connected between two adjacent second cathode blocks 320, and the fifth insulating block 603 is connected between two adjacent second light-emitting devices 120. The fourth electrical connection unit 80 includes a sixth insulating block 801, a fifth conductive block 802, and a seventh insulating block 803 which are stacked. The fifth conductive block 802 is electrically connected between two adjacent first cathode units 301, and the seventh insulating block 803 is connected between two adjacent first light-emitting units 101. The fifth electrical connection unit 90 includes an eighth insulating block 901, a sixth conductive block 902, and a ninth insulating block 903 which are stacked, the sixth conductive block 902 is electrically connected between two adjacent second cathode units 302, and the ninth insulating block 903 is connected between two adjacent second light-emitting units 102.

It may be understood that, the structures of the second electrical connection unit 50, the third electrical connection unit 60, the fourth electrical connection unit 80, and the fifth electrical connection unit 90 may be the same. The arrangement of the second insulating block 501, the fourth insulating block 601, the sixth insulating block 801, and the eighth insulating block 901 can respectively protect the corresponding third conductive block 502, the corresponding fourth conductive block 602, the corresponding fifth conductive block 802, and the corresponding sixth conductive block 902. The arrangement of the third insulating block 503, the fifth insulating block 603, the seventh insulating block 803, and the ninth insulating block 903 can isolate the corresponding light-emitting devices.

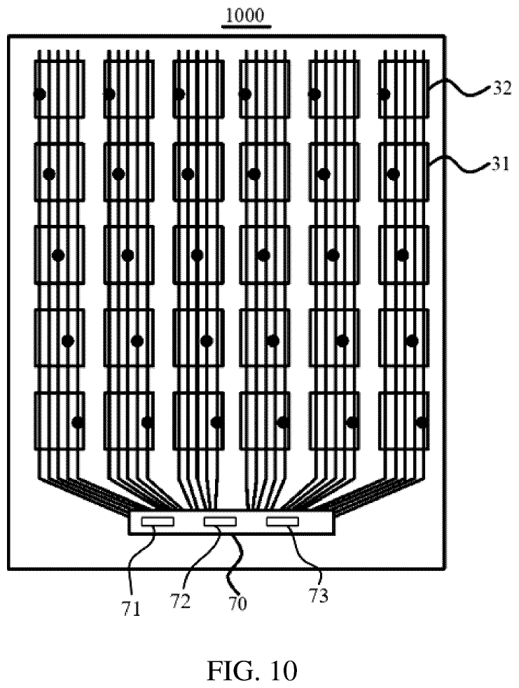

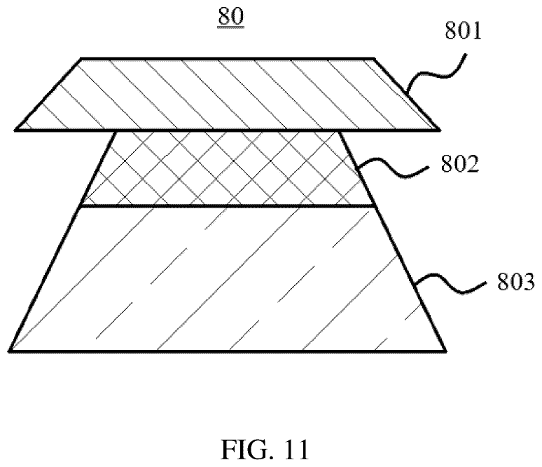

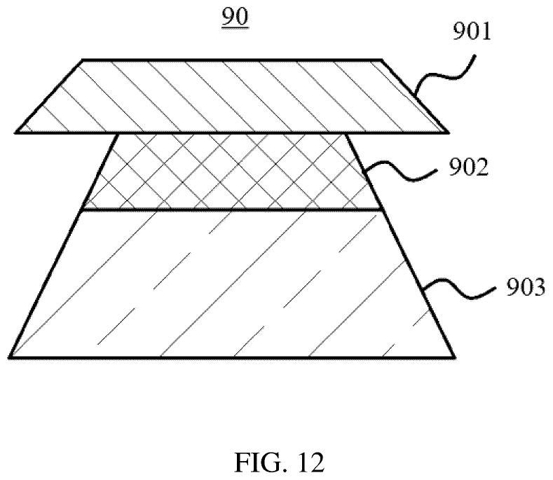

As illustrated in FIG. 10, the light-emitting assembly 100 further includes a first driving circuit 71 and a second driving circuit 72. The first driving circuit 71 is electrically connected to the anode module 20 and the cathode module 30, and the first driving circuit 71 is configured to provide a direct current signal during the display period. The second driving circuit 72 is electrically connected to the anode module 20 and the cathode module 30, and the second driving circuit 72 is configured to provide an alternating current signal during the touch period. The first driving circuit 71, the second driving circuit 72, and the regulating circuit 73 are integrated together.

In this embodiment, the first driving circuit 71, the second driving circuit 72, and the regulating circuit 73 form the aforementioned driving chip 70. However, in other embodiments, the first driving circuit 71 and the second driving circuit 72 may be integrated together to form the aforementioned driving chip 70, and the regulating circuit 73 may be arranged independently. Alternatively, one of the first driving circuit 71 and the second driving circuit 72 may be integrated with the regulating circuit 73 to form the aforementioned driving chip 70, while the other of the first driving circuit 71 and the second driving circuit 72 may be arranged independently.

By arranging the first driving circuit 71 and the second driving circuit 72, different driving signals may be provided for the light-emitting module 100 to achieve the switch between display period and touch period. By integrating the first driving circuit 71, the second driving circuit 72, and the regulating circuit 73 together, the integration degree of the light-emitting module 100 may be improved and the module size may be reduced.

The features mentioned above in the specification, claims, and drawings can be arbitrarily combined with each other as long as they are meaningful within the scope of the present disclosure. The advantages and features described for the light-emitting assembly 100 are applied to the touch display screen 1000 in a corresponding manner.

Although the embodiments of the disclosure have been illustrated or described above, it may be understood that the above-mentioned embodiments are exemplary, and should not be construed as limits to the disclosure. Those of ordinary skill in the art may make variations, modifications, replacements, transformations to the abovementioned embodiments within the scope of the disclosure, and these improvements and polishing shall also fall within the protection scope of the disclosure.

What is claimed is:

1. A light-emitting assembly, comprising:
a light-emitting module, comprising at least one first light-emitting unit and at least one second light-emitting unit, wherein the at least one first light-emitting unit each comprises a plurality of first light-emitting devices, and the at least one second light-emitting unit each comprises a plurality of second light-emitting devices;
an anode module, comprising at least one first anode unit and at least one second anode unit, wherein the at least one first anode unit is disposed on one side of the at least one first light-emitting unit and each comprises a plurality of first anode blocks, and one of the plurality of first anode blocks is electrically connected to one of the plurality of first light-emitting devices; the at least one second anode unit is disposed on one side of the at least one second light-emitting unit and each comprises a plurality of second anode blocks, and one of the plurality of second anode blocks is electrically connected to one of the plurality of second light-emitting devices;
a cathode module, comprising at least one first cathode unit and at least one second cathode unit, wherein the at least one first cathode unit is disposed on one side of the at least one first light-emitting unit facing away from the at least one first anode unit and each comprises a plurality of first cathode blocks, adjacent two of the plurality of first cathode blocks are electrically connected to each other, and one of the plurality of first cathode blocks is electrically connected to one of the plurality of first light-emitting devices; the at least one second cathode unit is disposed on one side of the at least one second light-emitting unit facing away from the at least one second anode unit and each comprises a plurality of second cathode blocks, adjacent two of the plurality of second cathode blocks are electrically connected to each other, and one of the plurality of second cathode blocks is electrically connected to one of the plurality of second light-emitting devices; wherein one or more of the at least one first cathode unit form a first touch electrode, and one or more of the at least one second cathode unit form a second touch electrode; and
a first electrical connection unit electrically connected between the first touch electrode and the second touch electrode, wherein the first electrical connection unit is in a first state during a display period to make the first touch electrode electrically connected to the second touch electrode, and the first electrical connection unit is in a second state during a touch period to make the first touch electrode disconnected from the second touch electrode.

2. The light-emitting assembly of claim 1, wherein the light-emitting assembly further comprises a regulating circuit electrically connected to the first electrical connection unit, wherein the regulating circuit is configured to provide a first driving voltage to the first electrical connection unit during the display period and provide a second driving voltage to the first electrical connection unit during the touch period, and the first driving voltage is higher than the second driving voltage.

3. The light-emitting assembly of claim 2, wherein the first electrical connection unit comprises a first conductive block, a second conductive block, and a resistance-adjustable block, wherein the first conductive block is electrically connected to one of the plurality of first cathode blocks in the first touch electrode, the second conductive block is electrically connected to one of the plurality of second cathode blocks in the second touch electrode, and the resistance-adjustable block is electrically connected to the regulating circuit; at least a portion of the resistance-adjustable block is connected between the first conductive block and the second conductive block, and the resistance-adjustable block exhibits a low-resistance state under the first driving voltage and exhibits a high-resistance state under the second driving voltage.

4. The light-emitting assembly of claim 3, wherein a dielectric constant of the resistance-adjustable block is greater than or equal to 15, and a band gap width of the resistance-adjustable block is greater than or equal to 3 electron volt (eV).

5. The light-emitting assembly of claim 3, wherein the first conductive block and the second conductive block are disposed in a same layer and spaced apart from each other, and the resistance-adjustable block comprises a first sub-resistance-adjustable block, a second sub-resistance-adjustable block, and a third sub-resistance-adjustable block sequentially connected; at least a portion of the first sub-resistance-adjustable block covers one side of the first conductive block facing away from the light-emitting module, at least a portion of the second sub-resistance-adjustable block is connected between the first conductive block and the second conductive block, and at least a portion of the third sub-resistance-adjustable block covers one side of the second conductive block facing away from the light-emitting module; and the first electrical connection unit further comprises a first insulating block connected between one of the plurality of first light-emitting devices and one of the plurality of second light-emitting devices.

6. The light-emitting assembly of claim 1, wherein the light-emitting assembly further comprises at least one second electrical connection unit and at least one third electrical connection unit, wherein a second electrical connection unit is electrically connected between adjacent two of the plurality of first cathode blocks, and a third electrical connection unit is electrically connected between adjacent two of the plurality of second cathode blocks.

7. The light-emitting assembly of claim 6, wherein the at least one first cathode unit is implemented as a plurality of first cathode units, the at least one second cathode unit is implemented as a plurality of second cathode units, and the light-emitting assembly further comprises at least one fourth electrical connection unit and at least one fifth electrical connection unit, wherein a fourth electrical connection unit is electrically connected between adjacent two of the plurality of first cathode units, and a fifth electrical connection unit is electrically connected between adjacent two of the plurality of second cathode units.

8. The light-emitting assembly of claim 7, wherein the at least one second electrical connection unit each comprises a second insulating block, a third conductive block, and a third insulating block which are stacked, wherein the third conductive block is electrically connected between adjacent two of the plurality of first cathode blocks, and the third insulating block is connected between adjacent two of the plurality of first light-emitting devices; the at least one third electrical connection unit each comprises a fourth insulating block, a fourth conductive block, and a fifth insulating block which are stacked, wherein the fourth conductive block is electrically connected between adjacent two of the plurality of second cathode blocks, and the fifth insulating block is connected between adjacent two of the plurality of second light-emitting devices; the at least one fourth electrical connection unit each comprises a sixth insulating block, a fifth conductive block, and a seventh insulating block which are stacked, wherein the fifth conductive block is electrically connected between adjacent two of the plurality of first cathode units, and the seventh insulating block is connected between adjacent two of the plurality of first light-emitting units; and the at least one fifth electrical connection unit each comprises an eighth insulating block, a sixth conductive block, and a ninth insulating block which are stacked, wherein the sixth conductive block is electrically connected between adjacent two of the plurality of second cathode units, and the ninth insulating block is connected between adjacent two of the plurality of second light-emitting units.

9. The light-emitting assembly of claim 2, wherein the light-emitting assembly further comprises a first driving circuit and a second driving circuit, wherein the first driving circuit is electrically connected to the anode module and the cathode module, the first driving circuit is configured to provide a direct current signal during the display period, the second driving circuit is electrically connected to the anode module and the cathode module, and the second driving circuit is configured to provide an alternating current signal during the touch period; and the first driving circuit, the second driving circuit, and the regulating circuit are integrated together.

10. The light-emitting assembly of claim 9, wherein the first driving circuit, the second driving circuit, and the regulating circuit form a driving chip.

11. A touch display screen, comprising a light-transmitting cover plate and a light-emitting assembly, wherein the touch display screen comprises a plurality of the light-emitting assemblies disposed in a same layer, and the light-transmitting cover plate covers a light-emitting side of the plurality of the light-emitting assemblies;
wherein the light-emitting assembly comprises:
a light-emitting module, comprising at least one first light-emitting unit and at least one second light-emitting unit, wherein the at least one first light-emitting unit each comprises a plurality of first light-emitting devices, and the at least one second light-emitting unit each comprises a plurality of second light-emitting devices;
an anode module, comprising at least one first anode unit and at least one second anode unit, wherein the at least one first anode unit is disposed on one side of the at least one first light-emitting unit and each comprises a plurality of first anode blocks, and one of the plurality of first anode blocks is electrically connected to one of the plurality of first light-emitting devices; the at least one second anode unit is disposed on one side of the at least one second light-emitting unit and each comprises a plurality of second anode blocks, and one of the plurality of second anode blocks is electrically connected to one of the plurality of second light-emitting devices;
a cathode module, comprising at least one first cathode unit and at least one second cathode unit, wherein the at least one first cathode unit is disposed on one side of the at least one first light-emitting unit facing away from the at least one first anode unit and each comprises a plurality of first cathode blocks, adjacent two of the plurality of first cathode blocks are electrically connected to each other, and one of the plurality of first cathode blocks is electrically connected to one of the plurality of first light-emitting devices; the at least one second cathode unit is disposed on one side of the at least one second light-emitting unit facing away from the at least one second anode unit and each comprises a plurality of second cathode blocks, adjacent two of the plurality of second cathode blocks are electrically connected to each other, and one of the plurality of second cathode blocks is electrically connected to one of the plurality of second light-emitting devices; wherein one or more of the at least one first cathode unit form a first touch electrode, and one or more of the at least one second cathode unit form a second touch electrode; and
a first electrical connection unit electrically connected between the first touch electrode and the second touch electrode, wherein the first electrical connection unit is in a first state during a display period to make the first touch electrode electrically connected to the second touch electrode, and the first electrical connection unit is in a second state during a touch period to make the first touch electrode disconnected from the second touch electrode.

12. The touch display screen of claim 11, wherein the light-emitting assembly further comprises a regulating circuit electrically connected to the first electrical connection unit, wherein the regulating circuit is configured to provide a first driving voltage to the first electrical connection unit during the display period and provide a second driving voltage to the first electrical connection unit during the touch period, and the first driving voltage is higher than the second driving voltage.

13. The touch display screen of claim 12, wherein the first electrical connection unit comprises a first conductive block, a second conductive block, and a resistance-adjustable block, wherein the first conductive block is electrically connected to one of the plurality of first cathode blocks in the first touch electrode, the second conductive block is electrically connected to one of the plurality of second cathode blocks in the second touch electrode, and the resistance-adjustable block is electrically connected to the regulating circuit; at least a portion of the resistance-adjustable block is connected between the first conductive block and the second conductive block, and the resistance-adjustable block exhibits a low-resistance state under the first driving voltage and exhibits a high-resistance state under the second driving voltage.

14. The touch display screen of claim 13, wherein a dielectric constant of the resistance-adjustable block is greater than or equal to 15, and a band gap width of the resistance-adjustable block is greater than or equal to 3 electron volt (eV).

15. The touch display screen of claim 13, wherein the first conductive block and the second conductive block are disposed in a same layer and spaced apart from each other, and the resistance-adjustable block comprises a first sub-resistance-adjustable block, a second sub-resistance-adjustable block, and a third sub-resistance-adjustable block sequentially connected; at least a portion of the first sub-resistance-adjustable block covers one side of the first conductive block facing away from the light-emitting module, at least a portion of the second sub-resistance-adjustable block is connected between the first conductive block and the second conductive block, and at least a portion of the third sub-resistance-adjustable block covers one side of the second conductive block facing away from the light-emitting module; and the first electrical connection unit further comprises a first insulating block connected between one of the plurality of first light-emitting devices and one of the plurality of second light-emitting devices.

16. The touch display screen of claim 11, wherein the light-emitting assembly further comprises at least one second electrical connection unit and at least one third electrical connection unit, wherein a second electrical connection unit is electrically connected between adjacent two of the plurality of first cathode blocks, and a third electrical connection unit is electrically connected between adjacent two of the plurality of second cathode blocks.

17. The touch display screen of claim 16, wherein the at least one first cathode unit is implemented as a plurality of first cathode units, the at least one second cathode unit is implemented as a plurality of second cathode units, and the light-emitting assembly further comprises at least one fourth electrical connection unit and at least one fifth electrical connection unit, wherein a fourth electrical connection unit is electrically connected between adjacent two of the plurality of first cathode units, and a fifth electrical connection unit is electrically connected between adjacent two of the plurality of second cathode units.

18. The touch display screen of claim 17, wherein the at least one second electrical connection unit each comprises a second insulating block, a third conductive block, and a third insulating block which are stacked, wherein the third conductive block is electrically connected between adjacent two of the plurality of first cathode blocks, and the third insulating block is connected between adjacent two of the plurality of first light-emitting devices; the at least one third electrical connection unit each comprises a fourth insulating block, a fourth conductive block, and a fifth insulating block which are stacked, wherein the fourth conductive block is electrically connected between adjacent two of the plurality of second cathode blocks, and the fifth insulating block is connected between adjacent two of the plurality of second light-emitting devices; the at least one fourth electrical connection unit each comprises a sixth insulating block, a fifth conductive block, and a seventh insulating block which are stacked, wherein the fifth conductive block is electrically connected between adjacent two of the plurality of first cathode units, and the seventh insulating block is connected between adjacent two of the plurality of first light-emitting units; and the at least one fifth electrical connection unit each comprises an eighth insulating block, a sixth conductive block, and a ninth insulating block which are stacked, wherein the sixth conductive block is electrically connected between adjacent two of the plurality of second cathode units, and the ninth insulating block is connected between adjacent two of the plurality of second light-emitting units.

19. The touch display screen of claim 12, wherein the light-emitting assembly further comprises a first driving circuit and a second driving circuit, wherein the first driving circuit is electrically connected to the anode module and the cathode module, the first driving circuit is configured to provide a direct current signal during the display period, the second driving circuit is electrically connected to the anode module and the cathode module, and the second driving circuit is configured to provide an alternating current signal during the touch period; and the first driving circuit, the second driving circuit, and the regulating circuit are integrated together.

20. The touch display screen of claim 19, wherein the first driving circuit, the second driving circuit, and the regulating circuit form a driving chip.
